(19) United States
(12) Patent Application Publication
(10) Pub. No.: US 2006/0232314 A1
(43) Pub. Date: Oct. 19, 2006

(54) Phase adjustment device, phase adjustment method, and semiconductor integrated circuit

(75) Inventors: Naohisa Hatani, Kyoto (JP); Mitsuhiko Otani, Hyogo (JP); Shinichi Ogita, Kyoto (JP); Kouji Yamaguti, Kyoto (JP); Takayasu Kito, Osaka (JP)

Correspondence Address: GREENBLUM & BERNSTEIN, P.L.C., 1950 ROLAND CLARKE PLACE, RESTON, VA, 20191, US

(73) Assignee: Matsushita Electric Industrial Co., Ltd., Osaka (JP)

(21) Appl. No.: 11/396,453

(22) Filed: Apr. 4, 2006

(30) Foreign Application Priority Data
Apr. 13, 2005 (JP) 2005-115306

(51) Int. Cl. H03K 5/13

(52) U.S. Cl. 327/231

(57) ABSTRACT

A phase adjustment device which adjusts a phase difference between a first output pulse signal and a second output pulse signal according to a phase difference between a first input pulse signal and a second input pulse signal, the phase adjustment device including: a first selection unit which selects one of the first input pulse signal and an adjustment pulse signal that is used for adjustment; a second selection unit which selects one of the second input pulse signal and the adjustment pulse signal; a first delay unit which delays the signal selected by the second selection unit, and a delay amount of the first delay unit is adjustable; a first output unit which outputs, as the first output pulse signal, the signal selected by the first selection unit; a second output unit which outputs, as the second output pulse signal, the signal delayed by the first delay unit; and a phase adjustment unit which adjusts the delay amount so as to equalize phases of the first output pulse signal and the second output pulse signal, in the case where both the first selection unit and the second selection unit have selected the adjustment pulse signal.

### BACKGROUND OF THE INVENTION

(1) Field of the Invention

The present invention relates to a phase adjustment device, a phase adjustment method and a semiconductor integrated circuit. In particular, the present invention relates to the phase adjustment device and the phase adjustment method which are used for a signal generation device.

(2) Description of the Related Art

In recent years an improvement in a processing speed by a signal processing device has been demanding along with high integration and high functionalization of a semiconductor integrated circuit device. With regard to a plurality of clock signals, data bas signal and the like which are inputted into a signal processing device performing high-speed processing, a phase required by the signal processing device needs to be guaranteed under a various circumstances. More specifically the signal generation device which provides a signal to the signal processing device is demanded to guarantee a phase of a pulse signal which is outputted under a various operational conditions.

As a method to guarantee a phase of a pulse signal outputted from the signal generation device, a technology which includes a phase adjustment circuit for executing fine adjustment of a phase of a pulse signal outputted from the signal generation device, and Delay Locked Loop (DLL) circuit technology for generating plural pulse signals whose phases are lagging behind a reference clock.

Hereafter, a phase adjustment circuit shown in a conventional example of Japanese Utility Model Application Publication No. H7-43551 (Patent Reference 1) will be explained referring to FIG. 1.

A phase adjustment circuit 900 shown in FIG. 1 generates a plurality of pulse signals in different phases through series-connected plurality of delay circuits 902, 903, 904 and 905 based on a reference clock pulse signal 901. A selection circuit 906 selects one of signals out of a plurality of pulse signals with different phases, and then outputs the selected pulse signal A1. Here, the phase of the pulse signal A1 can be adjusted to a desired phase depending on which phase of pulse signal is selected by the selection circuit 906. With regard to a control signal which controls the selection circuit 906, the adjustment value is stored in an external non-volatile storage circuit as a factory default. In addition a multi-stage delay circuit 907, which is composed of the delay circuits 902, 903, 904 and 905 and the selection circuit 906, is included for every outputting pulse signals, so that the plurality of outputting pulse signals A1 to An can be adjusted to an optimal phase.

However, in the phase adjustment circuit 900 used for the signal generation device shown in FIG. 1, the propagation delays from the reference clock pulse signal 901 for each of the outputting pulse signals A0 to An are different. The propagation delay is not stable due to the differences of a circuit power voltage and an operating temperature, and process variations. Thus, the phase is lagging behind the desired phase due to the differences of the operational conditions (power voltage and operating temperature); even a phase adjustment is executed under a certain operational condition.

As a method to reduce the effects by the power voltage, the operating temperature and the process variations, a technology using a DLL circuit is available. As an example of a conventional technology, a timing generation circuit using the DLL circuit shown in Japanese Laid-Open Patent Application No. H11-261408 (Patent Reference 2) will be explained referring to FIG. 2.

The timing generation circuit 1000 in FIG. 2 includes a DLL circuit 1006 and a plurality of signal generation circuits 1005. The DLL circuit 1006 generates plurality of internal clocks CK1 to CKm based on an inputted reference clock pulse signal 1001. The plurality of signal generation circuits 1005 shape the internal clocks CK1 to CKm, and output plurality of pulse signals C0 to Cn. The DLL circuit 1006 includes a variable delay line 1002, a phase comparative circuit 1003 and a control signal generation circuit 1004.

The variable delay line 1002 is composed of series-connected plurality of delay circuits. The delay time for each delay circuit can be varied by the control signal generated by the control signal generation circuit 1004. As an output from each delay circuit in the variable delay line 1002, the plurality of internal clocks CK1 to CKm with different phases are generated respectively.

The phase comparative circuit 1003 compares the phase of the internal clock CKm with the phase of the reference clock pulse signal 1001, and then detects a phase difference. The control signal generation circuit 1004 varies a delay amount in the variable delay line 1002 based on the detected differences so as to compose a feedback loop.

The feedback loop performs to finally equalize the phase of the internal clock CKm with a rising edge or a falling edge of the inputted reference clock pulse signal 1001. As a result, the propagation delay time between the inputted reference clock pulse signal 1001 and the internal clock CKm is equal to one cycle of the reference clock.

In addition, the respective delay stage outputs for CK1, CK2 to CK(m−1) for the variable delay line 1002 become clocks 1/m, 2/m to (m−1)/m cycle delay respectively from the reference clock pulse signal 1001.

The phase of the internal clocks CK1 to CK(m−1) are less affected with power voltage, temperature and process variation, so that a stable phase can be achieved. Thus, the signal generation circuits 1005 select a clock having a desired phase or performs a waveform shaping, so that a pulse signal with a stable pulse width and a phase can be generated.

(Patent Reference 1) Japanese Utility Model Application Publication No. H7-43551

(Patent Reference 2) Japanese Laid-Open Patent Application No. H11-261408

### SUMMARY OF THE INVENTION

In a phase adjustment circuit 900 in FIG. 1 and a timing generation circuit 1000 in FIG. 2, a load on a pulse outputting terminal to output an outputting pulse signal are different for the respective pulse outputting terminals. For example, one of the pulse signals to be outputted is a clock signal of the signal processing device, other pulse signals are the data bas signals, and thus there are many cases that the loads outside terminals are different. More particularly, in the case of a semiconductor integrated circuit system composed of different semiconductor integrated circuit for the signal generation device and the signal processing device, the pulse outputting terminals are largely affected with external loads. Furthermore, with regard to the output buffer of each pulse outputting terminals, the output buffer with the same configuration is not always used. In the case where the external load is different, or the output buffer configuration is different, even though a signal having a desired phase (the internal clocks CK1 to CK(m−1) and the like in FIG. 2) is generated, the phase of the pulse signal to be outputted lags. More specifically, there is a problem that the phase adjustment circuit 900 in FIG. 1 and the timing generation circuit 1000 in FIG. 2 are not able to perform high precision adjustment of the phase of the output pulse signal, in the case where the external load is different, the output buffer configuration is different, and the like.

In view of aforesaid problems, an object of the present invention is to provide a phase adjustment device, a phase adjustment method and a semiconductor integrated circuit which perform phase adjustment precisely and easily even when the external loads or the output buffer configurations are different.

In order to achieve the aforesaid object, according to the present invention, a phase adjustment device which adjusts a phase difference between a first output pulse signal and a second output pulse signal according to a phase difference between a first input pulse signal and a second input pulse signal. The phase adjustment device includes: a first selection unit which selects one of the first input pulse signal and an adjustment pulse signal that is used for adjustment; a second selection unit which selects one of the second input pulse signal and the adjustment pulse signal; a first delay unit which delays the signal selected by the second selection unit, and a delay amount of the first delay unit is adjustable; a first output unit which outputs, as the first output pulse signal, the signal selected by the first selection unit; a second output unit which outputs, as the second output pulse signal, the signal delayed by the first delay unit; and a phase adjustment unit which adjusts the delay amount so as to equalize phases of the first output pulse signal and the second output pulse signal, in the case where both the first selection unit and the second selection unit have selected the adjustment pulse signal. Here the first input pulse signal and the second input pulse signal can be an iteration clock pulse signal or a single pulse signal. In the case where at least one of the first input pulse signal and the second input pulse signal is a single pulse signal, the phase difference between the first input pulse signal and the second input pulse signal represents a time difference between the first input pulse signal and the second input pulse signal, that is, a phase difference where a cycle of single pulse is regarded as infinite.

According to this configuration, the phase adjustment device of the present invention adjusts the delay amount so as to equalize phases of the first output pulse signal and the second output pulse signal, in the case where both the first selection unit and the second selection unit have selected the adjustment pulse signal. Thus, it is possible to adjust the delay amount of the first delay unit for the delay caused by effects of output loads connected with the first output unit and the second output unit. In addition, it is possible to adjust the delay amount of the first delay unit for the delay caused by effects of configurations of the first output unit and the second output unit (driving capability and the like). In addition, in order to adjust values of the phase difference between the first output pulse signal and the second output pulse signal, it becomes more difficult to do so when a higher precision is required for phase. On the other hand, in the case of adjusting the phases to equalize them, it can be realized in a relatively easy way and inexpensive manner. Therefore, the phase adjustment device of the present invention is capable of performing phase adjustment with high precision and ease even when the external loads or the configurations of output buffers (the first output unit and the second output unit) are different.

Furthermore, the phase adjustment device may further include a second delay unit which delays the signal selected by the first selection unit, and the first output unit may output, as the first output pulse signal, the signal delayed by the second delay unit.

According to this configuration, the delay amount of the second delay unit is set an amount in between the adjustment range of the delay amount of the first delay unit, so that the delay amount of the first delay unit can be adjusted so as to equalize the phase of the first output pulse signal and the phase of the second output pulse signal regardless of delay/advance of the phase of the first output pulse signal and the second output pulse signal.

Furthermore, the phase adjustment device may further include a pulse generation unit which generates plural pulse signals from a reference clock signal so that each pulse signal has a different phase, and the plural pulse signals may include the first input pulse signal and the second input signal.

According to this configuration, the phase adjustment for the pulse signal generated by the pulse generation unit can be performed with high precision and ease even when the external loads or the configurations of output buffers (the first output unit and the second output unit) are different. For example the pulse generation unit which outputs a stable pulse signal which is less affected with power voltage, temperature and process variation is used, so that a phase difference for an output pulse signal caused by operation condition variation, process variation, difference of the external load and difference of the output buffer configuration can be adjusted so as to output a signal having a desired phase.

Furthermore, the pulse generation unit may be a DLL circuit.

According to this configuration, a phase adjustment for the pulse signal, which is outputted by the DLL circuit which outputs a signal with stable phase by adjusting a phase in the case where the operation conditions (power voltage and temperature) are changed, is performed with high precision and ease even when the external loads or the configurations of output buffers (the first output unit and the second output unit) are different. Therefore, the phase adjustment device of the present invention is capable of adjusting the phase difference of the output pulse signal caused by operation condition variation, process variation, difference of the external load and difference of the output buffer configuration, so as to output a signal having a desired phase.

Furthermore, the phase adjustment device may further include a first waveform shaping unit which shapes a waveform of the signal selected by the first selection unit so that the selected signal has a desired phase or a desired pulse width; and a second waveform shaping unit which shapes a waveform of the signal selected by the second selection unit so that the selected signal has a desired phase or a desired pulse width, and the first output unit may output, as the first output pulse signal, the signal whose waveform is shaped by the first waveform shaping unit, and the first delay unit may delay the signal whose waveform is shaped by the second waveform shaping unit.

According to this configuration, it is possible to adjust a phase and a pulse width for a signal whose waveform is shaped by the first waveform shaping unit and the second waveform shaping unit with high precision and ease even when the external load or the configuration of output buffers (the first output unit and the second output unit) are different.

Furthermore, the adjustment pulse signal may be one of the first input pulse signal and the second input pulse signal.

According to this configuration, an adjustment pulse signal is not necessary individually, so that the configuration of the phase adjustment device can be simplified.

Furthermore, the phase adjustment unit may include a changing unit which sequentially changes the delay amount of the first delay unit; a comparison unit which compares the phases of the first output pulse signal and the second output pulse signal; a storage unit which stores comparison results obtained by the comparison unit, by comparing the phases based on a corresponding delay amount that is sequentially changed by the changing unit; a determination unit which determines the delay amount so as to equalize the phases of the first output pulse signal and the second output pulse signal, based on the comparison results stored in the storage unit; and a control unit which controls the delay amount of the first delay unit, based on a determination result obtained by the determination unit.

According to this configuration, in a condition that the first selection unit and the second selection unit select adjustment pulse signals, it is possible to automatically adjust the delay amount so as to equalize the phase of the first output pulse signal and the phase of the second output pulse signal. In addition the adjusted delay amount is used, so that it is possible to equalize the phase difference between the first output pulse signal and the second output pulse signal and the phase difference between the first input pulse signal and the second input pulse signal.

Furthermore, the phase adjustment unit may operate when the phase adjustment device is initiated, or to automatically operate whenever necessary

According to this configuration, even when the operation condition (power voltage, temperature and the like) of the phase adjustment device is changed, a phase adjustment in the particular operation condition is performed. Therefore, even when the operation condition of the phase adjustment device is changed, it is possible to output the first output pulse signal and the second output pulse signal having a desired phase difference.

Furthermore, the semiconductor integrated circuit of the present invention, may include a phase adjustment device which adjusts a phase difference between a first output pulse signal and a second output pulse signal according to a phase difference between a first input pulse signal and a second input pulse signal, and the phase adjustment device may include: a first selection unit which selects one of the first input pulse signal and an adjustment pulse signal that is used for adjustment; a second selection unit which selects one of the second input pulse signal and the adjustment pulse signal; a first delay unit which delays the signal selected by the second selection unit, and a delay amount of the first delay unit is adjustable; a first output unit which outputs, as the first output pulse signal, the signal selected by the first selection unit; a second output unit which outputs, as the second output pulse signal, the signal delayed by the first delay unit; and a phase adjustment unit which adjusts the delay amount so as to equalize phases of the first output pulse signal and the second output pulse signal, in the case where both the first selection unit and the second selection unit have selected the adjustment pulse signal.

According to this configuration, it is possible to form a phase adjustment device on a chip of semiconductor integrated circuit, so that an inexpensive phase adjustment device can be realized. In addition, the phase adjustment device can be formed by combining each unit formed on plural semiconductor integrated circuits. Therefore, it is possible to simplify the configuration of each semiconductor integrated circuit; it is possible to use an existing semiconductor integrated circuit; and the like.

The phase adjustment device may be formed on a semiconductor substrate.

According to this configuration, it is possible to form the phase adjustment device on a chip of semiconductor integrated circuit, so that an inexpensive phase adjustment device can be realized.

Furthermore, a phase adjustment method of the present invention is executed by a phase adjustment device which adjusts a phase difference between a first output signal and a second output pulse signal according to a phase difference between a first input pulse signal and a second input pulse signal, the phase adjustment device includes: a first selection unit which selects one of the first input pulse signal and an adjustment pulse signal that is used for adjustment; a second selection unit which selects one of the second input pulse signal and the adjustment pulse signal; a first delay unit which delays the signal selected by the second selection unit, and a delay amount of the first delay unit is adjustable; a first output unit which outputs, as the first output pulse signal, the signal selected by the first selection unit; and a second output unit which outputs, as the second output pulse signal, the signal delayed by the first delay unit. The phase adjustment method includes: selecting the adjustment pulse signal by the first selection unit and the second selection unit; adjusting the delay amount so as to equalize phases of the first output pulse signal and the second output pulse signal, in the case where both the first selection unit and the second selection unit have selected the adjustment pulse signal; selecting the first input pulse signal by the first selection unit and selecting the second input pulse signal by the second selection unit; and propagating and outputting the first input pulse signal and the second input pulse signal using the delay amount adjusted in the adjusting of the delay amount. Thus, in a condition that an adjustment pulse signal is selected, the phase adjustment method of the present invention is capable of adjusting a delay amount difference between an input and an output so as to equalize the phases of plural output pulse signals which are propagated and outputted the adjustment pulse signal.

Thus, it is possible to adjust a delay amount for a delay caused by effects of the loads to a circuit with which plural output pulse signals are supplied. In addition, it is possible to adjust a delay amount for a delay caused by effects of configurations of output buffers and the like which outputs plural output pulse signals (driving capability and the like). In addition, in order to adjust value of the phase difference between plural output pulse signals, it becomes more difficult to do so when a higher precision is required for phase. However in the case of adjusting the phases to equalize them, it can be realized in a relatively easy way and inexpensive manner. Therefore, the phase adjustment method of the present invention is capable of performing phase adjustment with high precision and ease even when the external loads or the configurations of output buffers are different.

Furthermore, the adjusting the delay amount includes temporarily holding the adjusted delay amount, and the propagating and outputting includes reading the temporarily held delay amount.

Thus, the delay amount adjusted in the adjusting the delay amount can be used in a condition that plural input pulse signals are selected.

As described above, according to the present invention, the phase adjustment device, the phase adjustment method and the semiconductor integrated circuit which are capable of performing phase adjustment with high precision and ease, even when the external loads or the configurations of output buffers are different.

### FURTHER INFORMATION ABOUT TECHNICAL BACKGROUND TO THIS APPLICATION

The disclosure of Japanese Patent Application No. 2005-115306 filed on Apr. 13, 2005 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a block diagram showing a configuration of a conventional phase adjustment device;

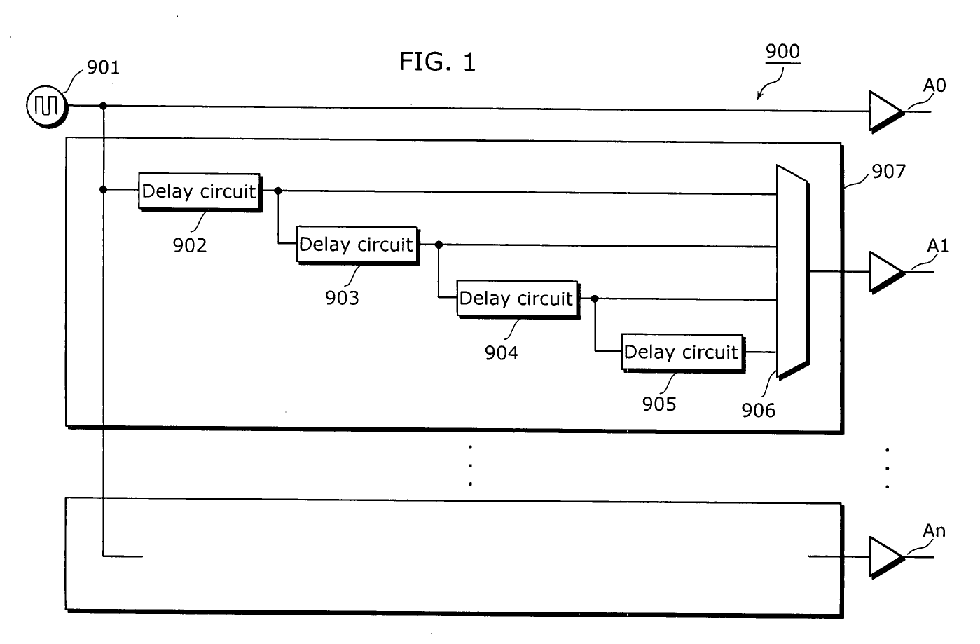

FIG. 2 is a block diagram showing a configuration of a DLL circuit;

FIG. 3 is a block diagram showing a configuration of a phase adjustment device according to a first embodiment of the present invention;

FIG. 4 is a block diagram showing a configuration of a multi-stage delay circuit;

FIG. 5 is a flowchart showing an operation of a phase adjustment device according to the first embodiment of the present invention;

FIG. 6 is a block diagram showing a configuration of a transformed phase adjustment device according to the first embodiment of the present invention;

FIG. 7 is a block diagram showing a configuration of the phase adjustment device according to a second embodiment of the present invention;

FIG. 8 is a block diagram showing a configuration of a phase adjustment unit;

FIG. 9 is a block diagram showing a configuration of the phase adjustment device according to a third embodiment of the present invention; and

FIG. 10 is a block diagram showing a configuration of the phase adjustment device according to a fourth embodiment of the present invention.

### DESCRIPTION OF THE PREFERRED EMBODIMENTS

Hereafter, embodiments of a phase adjustment device according to the present invention will be described referring to drawings.

### First Embodiment

The phase adjustment device according to the first embodiment of the present invention adjusts a delay caused by effects of the output loads of two signal paths, using an adjustment pulse. This allows such an adjustment to be performed with high precision and ease, even when the external loads and the output buffer configurations are different between the two signal paths.

Firstly, a configuration of the phase adjustment device according to the first embodiment of the present invention will be explained.

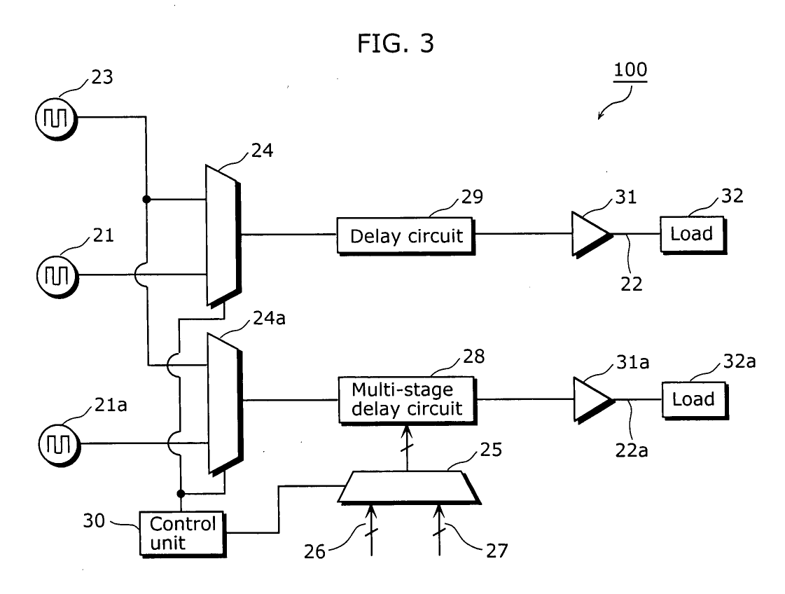

FIG. 3 is a block diagram showing a configuration of the phase adjustment device according to the first embodiment of the present invention. The phase adjustment device 100 shown in FIG. 3 is a semiconductor integrated circuit which adjusts a phase difference between an output pulse signal 22 and an output pulse signal 22a so that such phase difference becomes equal to a phase difference between an input pulse signal 21 and an input pulse signal 21a. The input pulse signal 21, the input pulse-signal 21a and a pulse signal for adjustment 23 (hereinafter referred to as an “adjustment pulse signal 23) are a clock signal which has a predetermined cycle, an iteration clock pulse signal, a single pulse signal or the like. Here, the phase difference also refers to a phase difference in the case where the time difference between single pulses, that is, a cycle of single pulse is regarded as infinite. The phase adjustment device 100 includes selection circuits 24, 24a and 25, a multi-stage delay circuit 28, a delay circuit 29, a control unit 30 and output buffers 31 and 31a.

The selection circuit 24 selects and outputs one of the input pulse signal 21 and the adjustment pulse signal 23. The selection circuit 24a selects and outputs one of the input pulse signal 21a and the adjustment pulse signal 23.

The selection circuit 25 selects and outputs one of an adjustment-time delay circuit control signal 26 and an after-adjustment delay circuit control signal 27.

The multi-stage delay circuit 28 is a delay circuit which is capable of changing a delay amount depending on the signal selected by the selection circuit 25. The multi-stage delay circuit 28 delays and outputs the signal selected by the selection circuit 24a.

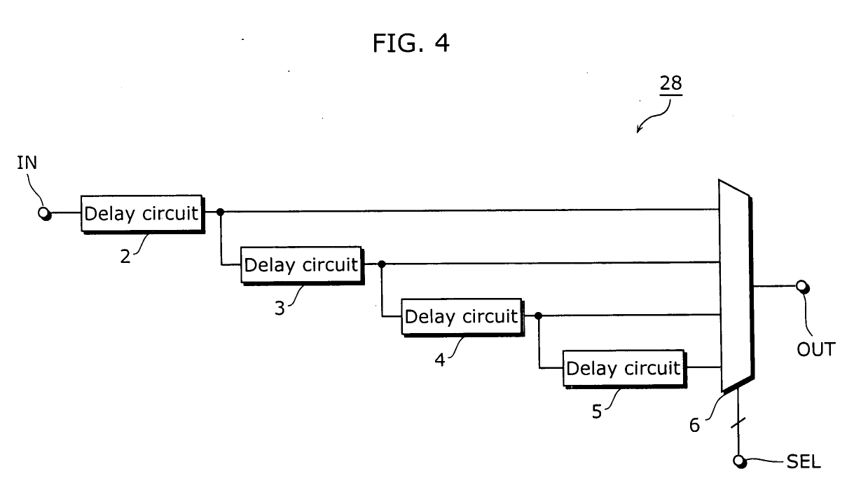

FIG. 4 is a block diagram showing a configuration of the multi-stage delay circuit 28. The multi-stage delay circuit 28 in FIG. 4 includes four delay circuits 2 to 5, and a selection circuit 6. Each signal inputted into an IN terminal goes through the delay circuits respectively having different number of stages, and the resulting signals are inputted into the selection circuit 6 capable of receiving four inputs. The delay circuits 2 to 5 are composed of, for example, plural stages of CMOS inverter. The selection circuit 6 selects one of the four signals with different phases according to a signal inputted into a SEL terminal, and then outputs the selected signal to an OUT terminal. For example, a signal inputted into the SEL terminal is a two-bit signal. In addition, the IN terminal in FIG. 4 is connected with an output of the selection circuit 24a, the OUT terminal is connected with an input of the output buffer 31a, and the SEL terminal is connected with an output of the selection circuit 25. It should be noted that the configuration of the multi-stage delay circuit 28 is not limited to the above exemplified configuration. For example, the number of the delay circuits (the number of signals received by the selection circuit 6) may be not less than five as long as the number of the delay circuits is a plural number.

The signal selected by the selection circuit 24 is inputted into the delay circuit 29. The delay circuit 29 adds a predetermined delay to the inputted signal and outputs the resulting signal. The delay circuit 29 is composed of, for example, plural stages of CMOS inverter. In addition, the delay amount of the delay circuit 29 is set an amount in between the variable delay amount of the multi-stage delay circuit 28. For example, the delay amount of the delay circuit 29 is set to an amount equivalent two stages in the delay circuits 2 to 5.

The control circuit 30 controls the selection circuits 24, 24a and 25.

The output buffer 31 outputs the signal, which was selected by the selection circuit 24 and was delayed by the delay circuit 29, as the output pulse signal 22. The output of the output buffer 31 is connected with a load 32. The output buffer 31a outputs the signal, which was selected by the selection circuit 24a and was delayed by the multi-stage delay circuit 28, as the output pulse signal 22a. The output of the output buffer 31a is connected with a load 32a. The loads 32 and 32a are an input load of a circuit which is supplied with the output pulse signals 22 or 22a, a wiring load and the like.

It should be noted that it is exemplified that the selection circuit 25 selects a signal 26 or 27 as a method to generate a control signal of the multi-stage delay circuit 28 in the present embodiment, but the configuration is not limited to the above exemplified configuration, and various modifications are available.

Next, an operation of the phase adjustment device 100 of the present embodiment will be described.

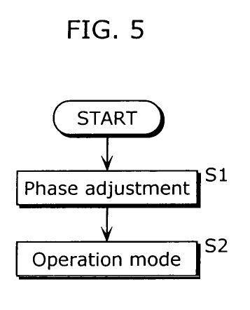

FIG. 5 is a flowchart showing the operation of the phase adjustment device 100 according to the present embodiment.

Firstly, phase adjustment is performed between the output pulse signal 22 and the output pulse signal 22a (step S1). At the time of the adjustment, the selection circuits 24 and 24a select the adjustment pulse signal 23, and the selection circuit 25 selects the adjustment-time delay circuit control signal 26 according to a signal from the control circuit 30.

Different adjustment-time delay circuit control signals 26 are sequentially inputted. Comparison is made between the phases of the output pulse signals 22 and 22a, which are propagated as the adjustment pulse signals 23, for each of the adjustment-time delay circuit control signals 26, and then the difference of the delay amount between the input and the output are respectively adjusted so as to equalize the phases of the output pulse signals 22 and 22a. More specifically, the delay of the multi-stage delay circuit 28 is adjusted so as to equalize the phases of the output pulse signals 22 and 22a. The optimized value of the adjustment-time delay circuit control signal 26 is held as an after-adjustment delay circuit control signal 27.

After the phase adjustment, the mode is changed to a normal operation mode (step S2). In the normal operation mode, the selection circuit 24 selects the input pulse signal 21, and the selection circuit 24a selects the input pulse signal 21a, and the selection circuit 25 selects an after-adjustment delay circuit control signal 27 according to a control signal from the control unit 30. The phase adjustment device 100 reads the after-adjustment delay circuit control signal 27, propagates the input pulse signals 21 and 21a using the after-adjustment delay circuit control signal 27, and outputs them as the output pulse signals 22 and 22a.

At the time of the adjustment (step S1), the phases of the output pulse signals 22 and 22a, which are outputted when the adjustment pulse signal 23 is selected, have been adjusted so as to be equal, so that the propagation delay from the input pulse signal 21 to the output pulse signal 22 is equal to the propagation delay from the input pulse signal 21a to the output pulse signal 22a. Therefore, the phase difference between the output pulse signals 22 and 22a is equal to the phase difference between the input pulse signals 21 and 21a.

As described above, the phase adjustment device 100 of the present embodiment adjusts the phase difference between the output pulse signals 22 and 22a in a state that the outputs of the output buffers 31 and 31a are connected with the loads 32 and 32a respectively. This makes it possible to perform phase adjustment considering effects of the loads 32 and 32a. Therefore, even when the loads 32 and 32a are different loads, the phase adjustment can be performed without any problems. In addition, in the case where configurations or driving capabilities are different between the output buffers 31 and 31a, the phase adjustment can be performed without any problems.

In addition, at the time of the phase adjustment (step S1), the timings of the output pulse signals 21 and 21a are adjusted to be equal. In the case of adjusting the value of a phase difference, it becomes more difficult to do so when a higher precision is required for phase. On the other hand, in the case of adjusting the phases to equalize them, it can be realized in a relatively easy way and inexpensive manner.

Furthermore, the phase adjustment device 100 according to the present embodiment, a component for determining a propagation delay of a path between an input pulse signal 21 and an output pulse signal 22, and a component for determining a propagation delay of a path between an input pulse signal 21a and an output pulse signal 22a are all composed of gate delays of a transistor. More specifically, a) delays of the selection circuit 24, the delay circuit 29 and the output buffer 31, which are components for determining a propagation delay of a path from an input pulse signal 21 to an output pulse signal 22, and b) delays of the selection circuit 24a, the multi-stage delay circuit 28 and the output buffer 31a, which are components for determining a propagation delay of a path from an input pulse signal 21a to an output pulse signal 22a, are both composed by gate delays of the transistor. Thus, the delays of the both paths are changed with the same tendency, when the circuit has an effect such as variations in power voltage, operating temperature, and process variations. In other words, the phase adjustment device 100 of the present embodiment is able to adjust the phase difference between the output pulse signals 22 and 22a so that such phase difference is relatively equal to the phase difference between the input pulse signals 21 and 21a, even in the case where the absolute value of the propagation delay is changed due to variations in power voltage, operating temperature, and process variations.

As described above, the first embodiment of the present invention provides the phase adjustment device which is capable of performing phase adjustment with high precision and ease even when external loads and the output buffer configurations are different. In addition, the phase adjustment device is provided which is capable of controlling a phase lag caused by variations in power voltage, operating temperature, and process variations.

It should be noted, as described above, that the delay circuit 29 is provided between the output of the selection circuit 24 and the input of the output buffer 31, but the output of the selection circuit 24 may be connected directly with the input of the output buffer 31. In this case, although only an adjustment to delay the phase of the output pulse signal 22a by the multi-stage delay circuit 28 can be performed, this configuration can be used for the cases such as where the load 32 is greater than the load 32a. In addition, a delay circuit capable of changing delay amounts may be used for the delay circuit 29.

Furthermore, as described above, the number of output pulse signals to be adjusted is two, but the number of output pulse signals to be adjusted can be an arbitrary number which is not less than two.

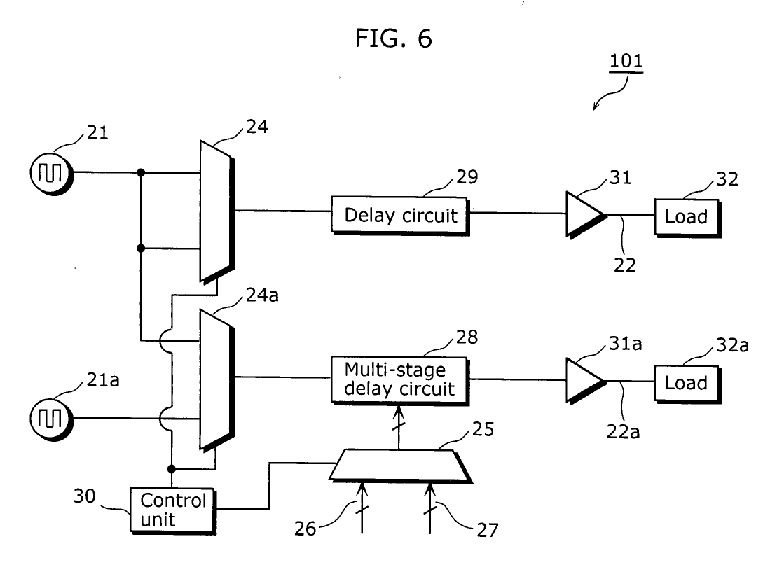

Furthermore, as described above, a signal which is different from the input pulse signals 21 and 21a is used as the adjustment pulse signal 23 used at the time of adjustment, but the input pulse signals 21 and 21a may be used instead of the adjustment pulse signal 23 at the time of adjustment. FIG. 6 is a block diagram showing a configuration of the phase adjustment device in the case where the input pulse signal 21 is used as an adjustment pulse. The input pulse signal 21 may be selected at the time of adjustment as an adjustment pulse as in the case of a phase adjustment device 101 shown in FIG. 6.

### Second Embodiment

A phase adjustment device according to the second embodiment of the present invention additionally includes a phase adjustment unit which automatically judges a phase difference between two signal paths, compared with the phase adjustment device 100 of the first embodiment.

Firstly, a configuration of the phase adjustment device according to the second embodiment of the present invention will be explained.

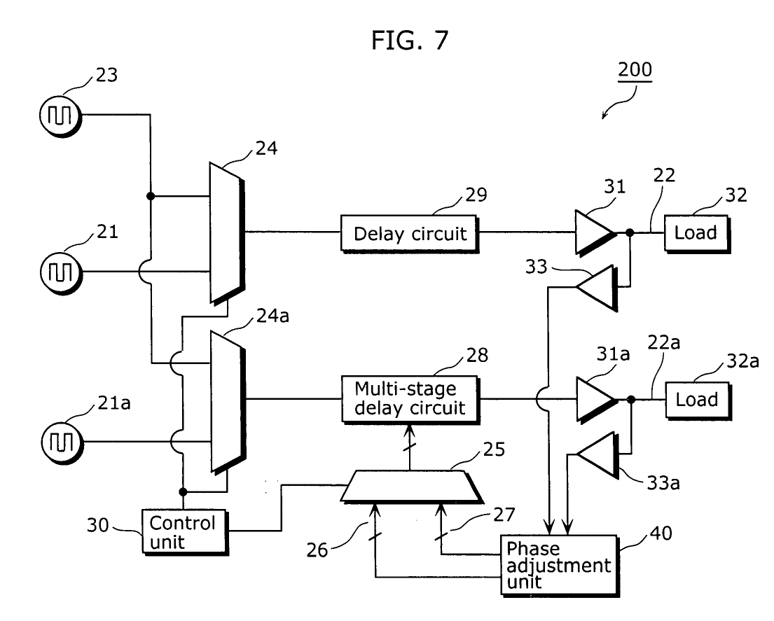

FIG. 7 is a block diagram showing the configuration of a phase adjustment device 200 according to the second embodiment of the present invention. The phase adjustment device 200 shown in FIG. 7 is a semiconductor integrated circuit which adjusts a phase difference between an output pulse signal 22 and an output pulse signal 22a so that such phase difference becomes equal to a phase difference between an input pulse signal 21 and an input pulse signal 21a. The phase adjustment device 200 is different from the phase adjustment device 100 of the first embodiment shown in FIG. 3 in that the phase adjustment device 200 additionally includes buffers 33 and 33a, as well as a phase adjustment unit 40. It should be noted that the same components as those shown in FIG. 3 are denoted by the same reference numbers, and the descriptions of such components will not be included in this embodiment.

The phase adjustment unit 40 adjusts a delay amount of the multi-stage delay circuit 28 so as to equalize the phases of the output pulse signals 22 and 22a at the time of the adjustment. The phase adjustment unit 40 detects the outputs of the adjustment-time delay circuit control signal 26 and the after-adjustment delay circuit control signal 27, and detects a phase difference between the output pulse signals 22 and 22a. In addition, the output pulse signal 22 is inputted into the phase adjustment unit 40 through the buffer 33a. The output pulse signal 22a is inputted into the phase adjustment unit 40 through the buffer 33a.

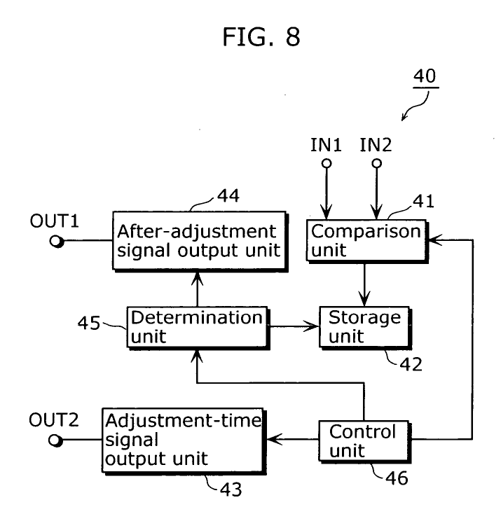

FIG. 8 is a block diagram showing a configuration of the phase adjustment unit 40 shown in FIG. 7. The phase adjustment unit 40 shown in FIG. 8 includes a comparison unit 41, a storage unit 42, an adjustment-time signal output unit 43, an after-adjustment signal output unit 44, a determination unit 45 and control unit 46.

The comparison unit 41 compares phases between a pulse signal inputted into an IN1 terminal and a pulse signal inputted into an IN2 signal. For example, the comparison unit 41 detects whether the pulse signal inputted into the IN2 terminal is high or low (H/L) at a rising edge (and/or falling edge) of the signal inputted into the IN1 terminal, in order to compare a phase of the pulse signal inputted into the IN1 terminal to a phase of the pulse signal inputted into the IN2 terminal.

The storage unit 42 stores a result of the comparison performed by the comparison unit 41.

At the time of the phase adjustment, the adjustment-time signal output unit 43 sequentially outputs the adjustment-time delay circuit control signal 26 for changing the delay amount of the multi-stage delay circuit 28, into an OUT2 terminal.

At the operation mode, the after-adjustment signal output unit 44 outputs the after-adjustment delay circuit control signal 27 to an OUT1 terminal.

The determination unit 45 determines the most appropriate delay amount based on the result stored in the storage unit 42. In other words, at the time of the phase adjustment, the determination unit 45 determines, based on the comparison result stored in the storage unit 42, the delay amount of the multi-stage delay circuit 28 by which the phase of the output pulse signal 22 becomes equal to the phase of the output pulse signal 22a.

The control unit 46 controls the comparison unit 41, the adjustment-time signal output unit 43, and the determination unit 45, at the time of the phase adjustment.

It should be noted that, in FIG. 8, the IN1 terminal is connected to an output of the buffer 33, the IN2 terminal is connected to an output of the buffer 33a, and the OUT1 and OUT2 terminals are connected to the selection circuit 25.

Next, an operation of the phase adjustment device 200 of the second embodiment of the present invention will be described. It should be noted that a flow of the operation of the phase adjustment device 200 of the second embodiment is the same as shown in FIG. 5.

Firstly, the phase adjustment between the path for outputting the output pulse signal 22 and the path for outputting the output pulse signal 22a is performed (step S1). At the time of the adjustment, the selection circuits 24 and 24a select the adjustment pulse signal 23, and the selection circuit 25 selects the adjustment-time delay circuit control signal 26 according to a signal from the control circuit 30.

The adjustment-time signal output unit 43 sequentially changes the adjustment-time delay circuit control signal 26 under the control of the control unit 46. For example, the adjustment-time delay circuit control signal 26 is a signal having two bits, and the adjustment-time signal output unit 43 sequentially outputs four patterns (00, 01, 10, 11) of the adjustment-time delay circuit control signal 26. By changing the adjustment-time delay circuit control signal 26, the delay amount of the multi-stage delay circuit 28 is changed to be sequentially increased (or reduced) Thereby, the phase of the output pulse signal 22a is sequentially delayed (or advanced).

The comparison unit 41 compares the phases of the output pulse signals 22 and 22a to each of the four patterns of the adjustment-time delay circuit control signal 26, respectively, under the control of the control unit 46. The storage unit 42 stores each comparison results performed by the comparison unit 41 using each delay amount of the multi-stage delay circuit 28 which has been changed by the adjustment-time signal output unit 43.

After the phase comparison to four patterns is complete, the determination unit 45 determines, under the control of the control unit 46, using the comparison results stored into the storage unit 42, a value that is the most appropriate delay amount of the adjustment-time delay circuit control signal 26. For example, the determination unit 45 determines, as the most appropriate value, a value of the adjustment-time delay circuit control signal 26 obtained immediately prior to (or immediate before) reversal of delay and advance of the phases of the output pulse signals 22 and 22a. More specifically, when a value of the output pulse signal 22a at a rising edge of the output pulse signal 22 is “high, high, low, low” depending on the respective four patterns of the adjustment-time delay circuit control signal 26, the value of output pulse signal 22a changes from high to low between a pattern 2 (the second pattern in the four patterns) and a pattern 3 (the third pattern in the four patterns), so that the determination unit 45 determines that the pattern 2 (or the pattern 3) is the most appropriate value of the adjustment-time delay circuit control signal 26.

After the determination of the most appropriate value of the adjustment-time delay circuit control signal 26, the determination unit 45 outputs the most appropriate value of the adjustment-time delay circuit control signal 26 to the after-adjustment signal output unit 44. The after-adjustment signal output unit 44 holds the most appropriate value of the adjustment-time delay circuit control signal 26 which has been sent from the determination unit 45, as the after-adjustment delay circuit control signal 27.

After the phase adjustment, the mode is changed to the normal operation mode (step S2). At the normal operation mode, the selection circuit 24 selects the input pulse signal 21 and the selection circuit 24a selects the input pulse signal 21a, and the selection circuit 25 selects an after-adjustment delay circuit control signal 27 according to a signal from the control unit 30. Further, the after-adjustment signal output unit 44 controls the delay amount of the multi-stage delay circuit 28, based on the determination result of the determination unit 45 at the time of the phase adjustment (step S1). In other words, the after-adjustment signal output unit 44 outputs the most appropriate value of the adjustment-time delay circuit control signal 26 which has been detected as the after-adjustment delay circuit control signal 27 at the step S1.

As described above, in the phase adjustment device 200 according to the second embodiment, at the time of the phase adjustment (step S1), the phase adjustment unit 40 compares the phases between the output pulse signals 22 and 22a, then determines a value of the adjustment-time delay circuit control signal 26 by which the phases become the most nearly equal and holds the determined value. The value of the adjustment-time delay circuit control signal 26 by which the phases become the most nearly equal is held as the after-adjustment delay circuit control signal 27, and used to decide the delay amount of the multi-stage delay circuit 28 at the normal operation mode (step S2).

Thereby, the phase adjustment device 200 according to the second embodiment has a further effect of performing the phase adjustment automatically, in addition to the effects according to the phase adjustment device 100 of the first embodiment. Thus, the phase adjustment can be performed when the system is initiated or regularly as needed. Accordingly, the phase can be adjusted to as the most appropriate phase for the operational conditions, even when the operating conditions (power voltage, temperature, and the like) are varied.

As described above, the second embodiment of the present invention provides the phase adjustment device which is capable of performing phase adjustment with high precision and ease even when the external loads and the output buffer configurations are different. In addition, the phase adjustment device is provided which is capable of controlling a phase lag caused by variations in power voltage, operating temperature, and process variations.

It should be noted that, in the above description, the comparison unit 41 compares the delay/advance of the phases of the output pulse signals 22 and 22a at the time of the phase adjustment, but the comparison unit 41 may detect an absolute value of the phase difference. In such a case, the determination unit 45 can determine the delay amount of the multi-stage delay circuit 28 that is appropriate more than the absolute value of the phase difference, which makes it possible to realize the phase adjustment with higher precision. It should be also noted that the present invention is not limited to the configuration shown in FIG. 8, but may be any configurations as far as the configurations have the same functions as described above. It should be also noted that the most appropriate value of the adjustment-time delay circuit control signal 26 detected as the time of the phase adjustment is held in the after-adjustment signal output unit 44, but the value may be held in another block. For example, the determination unit 45 may hold the most appropriate value of the adjustment-time delay circuit control signal 26.

### Third Embodiment

The third embodiment of the present invention describes when output signals from the DLL circuit are used as the input pulse signals 21 and 21a of the phase adjustment device 200 of the second embodiment.

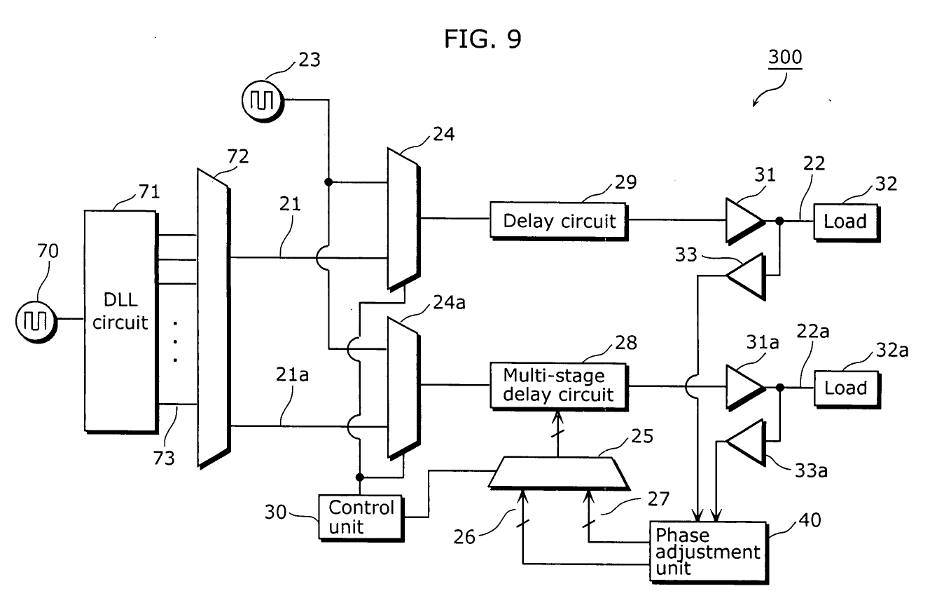

FIG. 9 is a block diagram showing a configuration of a phase adjustment device 300 according to the third embodiment of the present invention. It should be noted that the same components as those shown in FIG. 7 are denoted by the same reference numbers, and the descriptions of such components will not be included in this embodiment.

The phase adjustment device 300 shown in FIG. 9 adjusts a phase difference between output pulse signals 22 and 22a to be outputted after: inputting a reference clock pulse signal 70 into a DLL circuit 71 to generate a plurality of phase-lagged pulse signals 73; selecting the pulse signals 21 and 21a, which are desired phases, from the phase-lagged pulse signals 73; and propagating the selected the pulse signals 21 and 21a. The phase adjustment device 300 further includes a DLL circuit 71 and a selection circuit 72, in addition to the configuration of the phase adjustment device 200 of the second embodiment shown in FIG. 7.

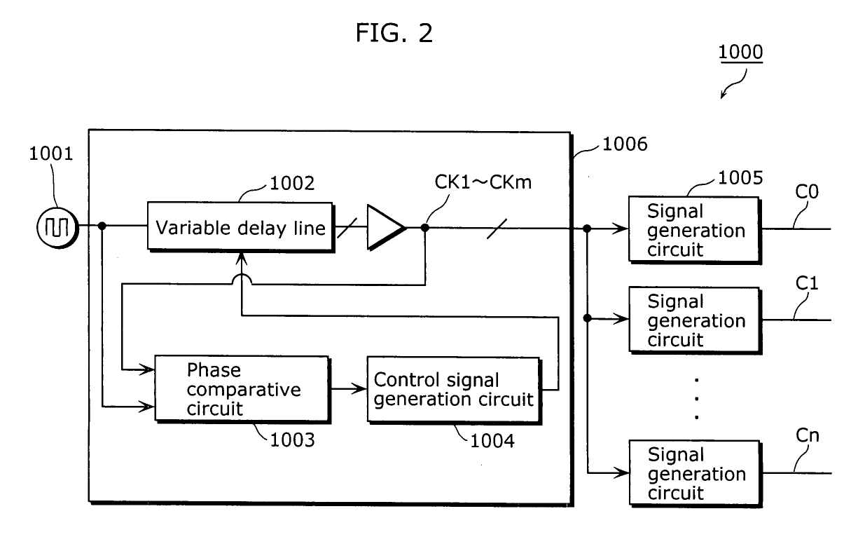

The DLL circuit 71 detects a phase difference between internal pulses, adjusts the phase difference, and outputs the plurality of phase-lagged pulse signals 73 each of which has a different phase. For example, the DLL circuit 1006 and the timing generation circuit 1000 shown in FIG. 2 can be used as the DLL circuit 71. The DLL circuit 71 generates, from the reference clock pulse signal 70 which is inputted from the outside, a plurality of phase-lagged pulse signals 73 having different phases, and outputs the phase-lagged pulse signals 73 to the selection circuit 72. It should be noted that, even when the operating conditions are varied, the DLL circuit 71 can output pulse signals having a desired phase difference.

The selection circuit 72 selects two arbitrary signals from the different phase-lagged pulse signals 73 which are outputted by the DLL circuit 71 and have different phases, and outputs the selected signals as the pulse signals 21 and 21a. The two signals selected by the selection circuit 72 become the input pulse signals 21 and 21a in the above-described second embodiment.

An operation of the phase adjustment device 300 according to the third embodiment is the same as described for the phase adjustment device 200 according to the second embodiment, and firstly phase adjustment between the path for outputting the output pulse signal 22 and a path for outputting the output pulse signal 22a. At the time of the adjustment, the selection circuits 24 and 24a select the adjustment pulse signal 23, and the selection circuit 25 selects the adjustment-time delay circuit control signal 26 according to a signal from the control circuit 30.

The phase adjustment unit 40 sequentially changes the adjustment-time delay circuit control signal 26 and detects a delay amount of the multi-stage delay circuit 28 by which the phase of the output pulse signal 22 becomes equal to the phase of the output pulse signal 22a. Then, the optimized value of the adjustment-time delay circuit control signal 26 is held into the phase adjustment unit 40 as the after-adjustment delay circuit control signal 27.

After the phase adjustment, the mode is changed to the operation mode. At the operation mode, the selection circuit 24 selects the input pulse signal 21 and the selection circuit 24a selects an input pulse signal 21a, and the selection circuit 25 selects an after-adjustment delay circuit control signal 27 according to a signal from the control unit 30.

At the time of the phase adjustment, the adjustment is performed to set the respective phases of the output pulse signals 22 and 22a which are outputted when the adjustment pulse signal 23 is selected, so that a propagation delay time from the input pulse signal 21 to the output pulse signal 22 becomes equal to a propagation delay time from the input pulse signal 21a to the output pulse signal 22a. That is, the phase difference between the output pulse signals 22 and 22a becomes equal to the phase difference between the output pulse signals 21 and 21a.

As described above, in the phase adjustment device 300 according to the third embodiment, the pulse signals 21 and 21a are selected from the phase-lagged pulse signals 73 which have high precision and generated in the DLL circuit 71. Therefore, the phase difference between the output pulse signals 21 and 21a is not affected by power voltage, operating temperature, and process variation. Furthermore, the phase adjustment device 300 according to the third embodiment adjusts the phase difference between the output pulse signals 22 and 22a, in a situation where the loads 32 and 32a are connected to the outputs of the output buffers 31 and 31a, respectively. Thereby, even when the load 32 is different from the load 32a, the phase adjustment can be performed without any problems. Additionally, even when a configuration or driving performance of the output buffer 31 is different from a configuration or driving performance of the output buffer 31a, the phase adjustment can be performed without any problems. Accordingly, the phase adjustment device 300 according to the third embodiment can perform the phase adjustment for the pulse signals having high precision, which are generated by the DLL circuit 71 and not affected by the power voltage, operating temperature, and process variation, using the effects of the loads 32 and 32a, and the like. Thus, the phase adjustment device 300 according to the third embodiment is able to adjust the phase lag of the output pulse signals which is caused by the variation of the operating conditions, process variations, the difference of the external loads, the difference of the output buffer configurations, and is able to output signals having desired phases.

Further, if the above-described phase adjustment (step S1) is executed arbitrarily, only by changing the selected phase-lagged pulse signals 73 depending on the necessity, the output pulse signals 22 and 22a having desired phases can be obtained. That is, when the selection circuit 72 changes the signal to be selected, the phase adjustment (step S1) is not necessary to be performed again.

As described above, the third embodiment of the present invention provides the phase adjustment device which is capable of performing the phase adjustment with high precision and ease even when the external loads and the output buffer configurations are different. In addition, the phase adjustment device is provided which is capable of controlling a phase lag caused by variations in power voltage, operating temperature, and process variations.

It should be noted that an arbitrary signal can be used as the adjustment pulse signal 23. For example, the reference clock pulse signal 70 may be used as the adjustment pulse signal 23.

### Fourth Embodiment

A phase adjustment device according to a fourth embodiment of the present invention adjusts the phase of a signal obtained by shaping the waveform of the input pulse signal.

Firstly, a configuration of the phase adjustment device according to the fourth embodiment of the present invention will be described.

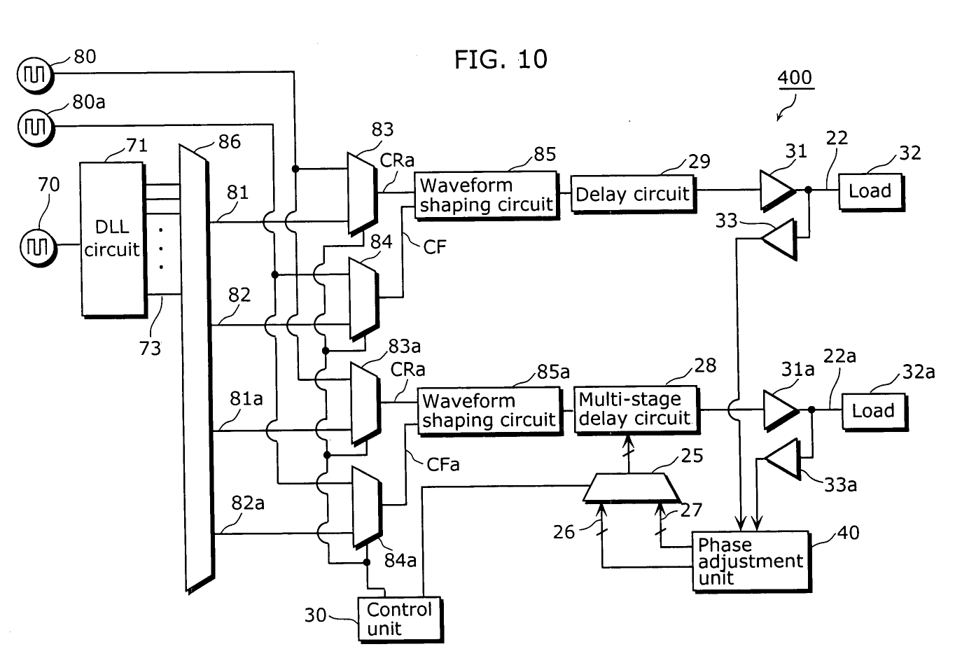

FIG. 10 is a block diagram showing a configuration of a phase adjustment device 400 according to the fourth embodiment of the present invention. It should be noted that the same components as those shown in FIG. 9 are denoted by the same reference numbers, and the descriptions of such components will not be included in this embodiment.

The phase adjustment circuit 400 shown in FIG. 10 adjusts a phase difference between output pulse signals 22 and 22a to be outputted after: obtaining the phase-lagged pulse signals 73 by inputting a reference clock pulse signal 70 into a DLL circuit 71; selecting the pulse signals 81, 82, 81a and 82a, which are desired phases, from among phase-lagged pulse signals 73; and causing a propagation of a signal whose waveform has been shaped based on the pulse signals 81, 82, 81a and 82a. The phase adjustment device 400 differs from the configuration of the third embodiment shown in FIG. 9 in that it includes selection circuits 83, 83a, 84, 84a and 86, and waveform shaping circuits 85 and 85a.

The selection circuit 86 selects four arbitrary signals from the different pulse signals 73 outputted by the DLL circuit 71, and outputs the selected signals as the pulse signals 81, 82, 81a and 82a.

The selection circuit 83 selects one of the pulse signal 81 and an adjustment pulse signal 80, and outputs the selected one as a signal CR. The selection circuit 84 selects one of the pulse signal 82 and an adjustment pulse signal 80a, and outputs the selected one as a signal CF. The selection circuit 83a selects one of the pulse signal 81a and the adjustment pulse signal 80, and outputs the selected one as a signal CRa. The selection circuit 84a selects one of the pulse signal 82a and the adjustment pulse signal 80a, and outputs the selected one as a signal CFa.

The waveform shaping circuit 85 shapes the waveforms of the signals selected by the selection circuits 83 and 84 into the signals having desired phases or pulse widths. The waveform shaping circuit 85 outputs a signal having a waveform which rises at a rising edge timing of the signal CR and falls at a rising edge timing of the signal CF. The signal whose waveform has been shaped by the waveform shaping circuit 85 is inputted into a delay circuit 29. The waveform shaping circuit 85a shapes the waveforms of the signals selected by the selection circuits 83a and 84a into the signals having desired phases and pulse widths. The waveform shaping circuit 85a outputs a signal having a waveform which rises at a rising edge timing of the signal CRa and falls at a rising edge timing of the signal CFa. The signal whose waveform has been shaped by the waveform shaping circuit 85a is inputted into a multi-stage delay circuit 28.

In this embodiment, the adjustment pulse signals 80 and 80a may be arbitrary pulses. For example, they may be any of the reference clock pulse signal 70, the pulse signals 73 and 81, or the like. In addition, an arbitrary number of output pulse signals to be adjusted can be employed. Further, in this embodiment, the waveform shaping circuits 85 and 85a shape each of the waveforms of the input signals CR, CF, CRa and CFa as a rising timing pulse or a falling timing pulse. However, functions and configurations are not limited to them, and various forms can be employed.

Next, the functions of the phase adjustment device 400 of the fourth embodiment of the present invention will be described.

Firstly, phase adjustment between a path for outputting the output pulse signal 22 and a path for outputting the output pulse signal 22a is performed. At the time of the adjustment, the selection circuits 83 and 83a select the adjustment pulse signal 80, the selection circuit 84 and 84a select the adjustment pulse signal 80a and the selection circuit 25 selects the adjustment-time delay circuit control signal 26 according to a signal from the control circuit 30.

The waveform shaping circuit 85 shapes the waveform of a signal based on the signal CR and the signal CF so that the signal rises at the rising edge timing of the signal CR and falls at the rising edge timing of the signal CF, and outputs the signal to the delay circuit 29. More specifically, the waveform shaping circuit 85 outputs a signal which rises at the timing corresponding to the rising edge timing of the adjustment pulse signal 80 and falls at the timing corresponding to the rising edge timing of the adjustment pulse signal 80a.

The waveform shaping circuit 85a shapes the waveform of a signal based on the signal CRa and the signal CFa so that the signal rises at the rising edge timing of the signal CRa and falls the rising edge timing of the signal CFa, and outputs the signal to a multi-stage delay circuit 28. More specifically, the waveform shaping circuit 85a outputs the signal which rises at the timing corresponding to the rising edge timing of the adjustment pulse signal 80 and falls at the timing corresponding to the rising edge timing of the adjustment pulse signal 80a.

Next, the phase adjustment unit 40 changes the timing of the output pulse 22a by changing the adjustment-time delay circuit control signal 26 and changing delay time of the multi-stage delay circuit 28. The phase adjustment unit 40 compares one or both of the rising edge timing and falling edge timing of the output pulse signals 22 and 22a, automatically determines the value of an adjustment-time delay circuit control signal 26 which provides the most nearly equal phases of the output pulse signals 22 and 22a, and holds the determined value. Subsequently, the optimized value of the adjustment-time delay circuit signal 26 is held in a phase adjustment unit 40 as an after-adjustment delay circuit control signal 27.

After the phase adjustment, a mode is changed to an operation mode. In the operation mode, by a signal from the control circuit 30, the selection circuit 83 selects a pulse signal 81, the selection circuit 84 selects a pulse signal 82, the selection circuit 83a selects a pulse signal 81a, the selection circuit 84a selects a pulse signal 82a. In addition, the selection circuit 25 selects an after-adjustment delay circuit control signal 27.

During the operation mode, the waveform shaping circuit 85 shapes the signal which rises at the timing corresponding to the rising edge timing of the pulse signal 81 and falls at the timing corresponding to the rising edge timing of the pulse signal 82, and outputs the signal to the delay circuit 29. The waveform shaping circuit 85a shapes the signal which rises at the timing corresponding to the rising edge timing of the pulse signal 81a and falls at the timing corresponding to the rising edge timing of the adjustment pulse signal 82a, and outputs the signal to the multi-stage delay circuit 28.

At the time of the phase adjustment, the adjustment is performed to set the respective phases of the output pulse signals 22 and 22a, which are outputted when the adjustment pulse signals 80 and 80a are selected. Therefore, all the followings become equal: propagation delay time from the rising edge of the pulse signal 81 to the rising edge of the output pulse signal 22; propagation delay time from the rising edge of the pulse signal 82 to the falling edge of the output pulse signal 22; propagation delay time from the rising edge of the pulse signal 81a to the rising edge of the output pulse signal 22a; and propagation delay time from the rising edge of the pulse signal 82a to the falling edge of the output pulse signal 22a. In addition, even when an absolute value of the propagation delay time has changed due to a change in power voltage, operating temperature, and process variation, the phase difference of timings and the pulse widths of the output pulse signals 22 and 22a can be adjusted to be relatively equal to the relative phase differences among the pulse signals 81, 81a, 82 and 82a.

From the above-descriptions, the phase adjustment device 400 of the fourth embodiment of the present invention can adjust the phase difference of the two signals (output pulse signals 22 and 22a) to be shaped based on the rising edge timing of a signal which has been arbitrarily selected by the phase-lagged pulse signals 73. Here, the phase-lagged pulse signals 73 have been generated by a DLL circuit 71 and have high precision. In addition, since the phase differences among the pulse signals 81, 81a, 82 and 82a are selected from the highly-precise phase-lagged pulses 73 to be generated by the DLL circuit 71, it is not affected by the power voltage, operating temperature and process variations. Thus, it becomes possible to adjust a phase difference between the output pulse signals 22 and 22a and pulse widths of the respective pulses to a desired phase difference and desired pulse widths.

Furthermore, the phase adjustment device 400 according to this embodiment adjusts the phase difference between the output pulse signals 22 and 22a, in a situation where the loads 32 and 32a are connected to the outputs of the output buffers 31 and 31a respectively. Thereby, even when the load 32 is different from the load 32a, the phase adjustment can be performed without any problem. Additionally, even when a configuration or driving performance of the output buffer 31 is different from a configuration or driving performance of the output buffer 31a, the phase adjustment can be performed without any problem.

As described above, the fourth embodiment of the present invention provides the phase adjustment device which is capable of performing phase adjustment with high precision and ease even when external loads and the output buffer configurations are different. In addition, the phase adjustment device is provided which is capable of controlling a phase lag caused by variations in power voltage, operating temperature, and process variations.

The present invention is not limited to the above-described first to fourth embodiments, and various modifications and variations are possible without deviating from the scope of the present invention. In addition, the present invention is applicable to a signal processing system having a semiconductor integrated circuit to which the phase adjustment device of the present invention is applied, or to a semiconductor integrated circuit system including a driving system such as a hard disc, a solid-state imaging device and the like.

The phase adjustment device of the present invention is not limited to a configuration on a single semiconductor integrated circuit formed on a single semiconductor substrate. The phase adjustment device is further applicable to a semiconductor integrated circuit system configured to be divided semiconductor integrated circuits. For example, in the phase adjustment device 200 shown in FIG. 7, a selection circuit 25 and a phase adjustment unit 40 may be configured as another semiconductor integrated circuit.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

### INDUSTRIAL APPLICABILITY

The present invention is applicable to a phase adjustment device, a phase adjustment method, and a semiconductor integrated circuit. In particular, the present invention is applicable to a semiconductor integrated device which includes a signal generation device, a signal processing system and a driving system and the like having a phase adjustment device.

What is claimed is:

1. A phase adjustment device which adjusts a phase difference between a first output pulse signal and a second output pulse signal according to a phase difference between a first input pulse signal and a second input pulse signal, said phase adjustment device comprising:
a first selection unit operable to select one of the first input pulse signal and an adjustment pulse signal that is used for adjustment;
a second selection unit operable to select one of the second input pulse signal and the adjustment pulse signal;
a first delay unit operable to delay the signal selected by said second selection unit, and a delay amount of said first delay unit is adjustable;
a first output unit operable to output, as the first output pulse signal, the signal selected by said first selection unit;
a second output unit operable to output, as the second output pulse signal, the signal delayed by said first delay unit; and
a phase adjustment unit operable to adjust the delay amount so as to equalize phases of the first output pulse signal and the second output pulse signal, in the case where both said first selection unit and said second selection unit have selected the adjustment pulse signal.

2. The phase adjustment device according to claim 1, further comprising:
a second delay unit operable to delay the signal selected by said first selection unit,
wherein said first output unit is operable to output, as the first output pulse signal, the signal delayed by said second delay unit.

3. The phase adjustment device according to claim 1, further comprising:
a pulse generation unit operable to generate a plurality of pulse signals from a reference clock signal so that each pulse signal has a different phase,
wherein the plurality of pulse signals include the first input pulse signal and the second input signal.

4. The phase adjustment device according to claim 3,
wherein said pulse generation unit is a Delay Locked Loop circuit.

5. The phase adjustment device according to claim 1, further comprising:
a first waveform shaping unit operable to shape a waveform of the signal selected by said first selection unit so that the selected signal has a desired phase or a desired pulse width; and
a second waveform shaping unit operable to shape a waveform of the signal selected by said second selection unit so that the selected signal has a desired phase or a desired pulse width,
wherein said first output unit is operable to output, as the first output pulse signal, the signal whose waveform is shaped by said first waveform shaping unit, and
said first delay unit is operable to delay the signal whose waveform is shaped by said second waveform shaping unit.

6. The phase adjustment device according to claim 1,
wherein the adjustment pulse signal is one of the first input pulse signal and the second input pulse signal.

7. The phase adjustment device according to claim 1,
wherein said phase adjustment unit comprises:
a changing unit operable to sequentially change the delay amount of said first delay unit;
a comparison unit operable to compare the phases of the first output pulse signal and the second output pulse signal;
a storage unit operable to store comparison results obtained by said comparison unit, by comparing the phases based on a corresponding delay amount that is sequentially changed by said changing unit;
a determination unit operable to determine the delay amount so as to equalize the phases of the first output pulse signal and the second output pulse signal, based on the comparison results stored in said storage unit; and
a control unit operable to control the delay amount of said first delay unit, based on a determination result obtained by said determination unit.

8. The phase adjustment device according to claim 7,
wherein said phase adjustment unit is operable to operate when said phase adjustment device is initiated, or to automatically operate whenever necessary.

9. A semiconductor integrated circuit comprising,
a phase adjustment device which adjusts a phase difference between a first output pulse signal and a second output pulse signal according to a phase difference between a first input pulse signal and a second input pulse signal,
wherein said phase adjustment device includes:
a first selection unit operable to select one of the first input pulse signal and an adjustment pulse signal that is used for adjustment;
a second selection unit operable to select one of the second input pulse signal and the adjustment pulse signal;
a first delay unit operable to delay the signal selected by said second selection unit, and a delay amount of said first delay unit is adjustable;
a first output unit operable to output, as the first output pulse signal, the signal selected by said first selection unit;
a second output unit operable to output, as the second output pulse signal, the signal delayed by said first delay unit; and
a phase adjustment unit operable to adjust the delay amount so as to equalize phases of the first output pulse signal and the second output pulse signal, in the case where both said first selection unit and said second selection unit have selected the adjustment pulse signal.

10. The semiconductor integrated circuit according to claim 9,
wherein said phase adjustment device is formed on a semiconductor substrate.

11. A phase adjustment method for use by a phase adjustment device which adjusts a phase difference between a first output signal and a second output pulse signal according to a phase difference between a first input pulse signal and a second input pulse signal, the phase adjustment device including:
a first selection unit operable to select one of the first input pulse signal and an adjustment pulse signal that is used for adjustment;
a second selection unit operable to select one of the second input pulse signal and the adjustment pulse signal;
a first delay unit operable to delay the signal selected by the second selection unit, and a delay amount of the first delay unit is adjustable;
a first output unit operable to output, as the first output pulse signal, the signal selected by the first selection unit; and
a second output unit operable to output, as the second output pulse signal, the signal delayed by the first delay unit;
wherein said phase adjustment method comprises:
selecting the adjustment pulse signal by the first selection unit and the second selection unit;
adjusting the delay amount so as to equalize phases of the first output pulse signal and the second output pulse signal, in the case where both the first selection unit and the second selection unit have selected the adjustment pulse signal;
selecting the first input pulse signal by the first selection unit, and selecting the second input pulse signal by the second selection unit; and
propagating and outputting the first input pulse signal and the second input pulse signal using the delay amount adjusted in said adjusting of the delay amount.

12. The phase adjustment device according to claim 11,
wherein said adjusting the delay amount includes temporarily holding the adjusted delay amount, and
said propagating and outputting includes reading the temporarily held delay amount.
